(19) United States
(12) Patent Application Publication
(10) Pub. No.: US 2001/0026995 A1
(43) Pub. Date: Oct. 4, 2001

(54) Method of forming shallow trench isolation

(76) Inventor: Keita Kumamoto, Tokyo (JP)

Correspondence Address: HELFGOTT & KARAS, P.C., EMPIRE STATE BUILDING, 60TH FLOOR, NEW YORK, NY, 10118, US

(21) Appl. No.: 09/814,013

(22) Filed: Mar. 21, 2001

(30) Foreign Application Priority Data
Mar. 28, 2000 (JP) 89501/2000

(51) Int. Cl. H01L 21/76

(52) U.S. Cl. 438/424; 438/431

(57) ABSTRACT

The method of structuring shallow trench isolations is accomplished by forming mask patterns containing openings in semiconductor substrate; forming trenches on the semiconductor substrate by using openings; filling in openings and trenches with first silicon oxide film. A second silicon oxide film is formed and etched back after removing the mask patterning to form side walls on the side walls of first silicon oxide film. Then, the first silicon oxide film is removed from the element region after performing ion doping of element region to facilitate the formation of transistors.

### BACKGROUND OF THE INVENTION

1. Field of the Invention

The present invention generally relates to a method of forming shallow trench isolations (STI). In particular, it relates to a method of forming shallow trench isolations suitable for semiconductor integrated circuits with high integration, and which have little current leakage between adjacent transistors.

2. Description of Related Art

Recently, as the scaling down and high integration of semiconductor integrated circuits continue to advance, the issues of downsizing elements and downsizing the element isolation regions have become important engineering topics. In general, element isolation regions are usually formed by structuring a thick oxide film between element regions. Nowadays, an element isolation structure called trench isolation is often employed in order to reduce the size of element isolation regions. This trench isolation technique forms trenches on the semiconductor substrate, and isolates elements by embedding an insulating film or conductive film that has been coated with an insulating film in these trenches.

However, this trench isolation technique is problematic. FIG. 5 shows a conventional structure of shallow trench isolations. Trenches 6 have been formed on the surface of a silicon substrate 1, and in these trenches 6 a silicon oxide film 8 has been embedded. Transistor gate 25 is then formed on the insulating film between the trenches 6. With this conventional trench isolation technique, however, when wet-etching is performed to remove the insulation layer that was formed on the surface of the element regions, it is easy for pockets 15 to develop in the silicon oxide film 8 in the corners of the trenches 6 on the semiconductor substrate 1 because the etching of the silicon oxide film 8 progresses locally here. When transistors are formed in element regions adjacent to the silicon oxide film 8, these pockets 15 cause the electric field from the gate electrode 25 to concentrate towards the channel corners, which leads to a drop in the threshold voltage of these transistors and/or an increase in current leakage. As a result, the elimination or reduction of these pockets forming in the corners of the trenches has become an important point in developing techniques of forming trench isolations.

As an example, Japanese Patent Application Laid-open No. Hei 6-37178 discloses techniques whereby the upper surface of the material embedded in the trench are covered with a lid that is wider than the width of the trench, stopping the progression of etching in the corners of the insulating film within the trenches during the wet-etching process. This technique will now be described in detail while referencing FIGS. 6A to 6H.

FIGS. 6A to 6H are cross-sectional diagrams showing trench isolation as it is being formed in the formation process order of the conventional technique. As shown in FIG. 6A, the surface of silicon substrate 1 is oxidized so as to form silicon oxide film 2 with a thickness of, for example, 30 nm. On top of this, a silicon nitride film 3 with a thickness of, for example, 150 nm is formed using CVD (chemical vapor deposition). Then another layer of silicon oxide film 4 is laid on top of silicon nitride film 3 with a thickness of, for example, 300 nm. Next the element isolation region patterning is performed using photolithography, and the three-layer film 2, 3 and 4 on the element isolation region is etched off using RIE (reactive ion etching), forming openings 5.

As shown in FIG. 6B, a silicon oxide film 13 with a thickness, for example, of 150 nm is next deposited using LPCVD (low-pressure CVD) on the surface shown in FIG. 6A. Then after the wafer is annealed in a N₂ atmosphere at 900° C. for 60 minutes, oxidized silicon film 13 that had been deposited on the upper surface of substrate 1 and oxidized silicon film 4 is removed using full surface RIE, leaving behind a layer of silicon oxide film 13 on only the side walls of the three-layer film 2, 3, and 4 as shown in FIG. 6C.

The three-layer film 2, 3, and 4, and silicon oxide 13 film left on the side walls of this three-layer film are then used as an etching mask in order to etch silicon substrate 1 down a depth of, for example, 400 nm, forming trenches 6, as shown in FIG. 6D.

Next, as shown in FIG. 6E, silicon oxide films 4 and 13 are removed using wet-etching, leaving behind silicon nitride film 3. Then as shown in FIG. 6F, once the inner walls of trenches 6 have been oxidized and a silicon oxide film 7 has been formed with a thickness of, for example, 30 nm, a silicon oxide film 8 is deposited, for example with a thickness of up to 600 nm, filling in trenches 6 with silicon oxide. At this point, silicon oxide film 8 is also formed on top of silicon nitride film 3.

This silicon oxide film 8 is then etched back, as shown in FIG. 6G, using CMP (chemical mechanical polishing) or RIE until silicon nitride film 3 is exposed. Finally, as shown in FIG. 6H, silicon nitride film 3, which had been left behind is removed using wet-etching, and silicon oxide film 2 on the surface of element region 11 is also removed using wet-etching, completing trench isolation.

According to this technique described in the above paragraphs, in the process shown in FIG. 6F when silicon oxide film 8 is used to fill in trenches 6, or mask-patterned openings 5, a lid covering the trench 6 is formed since the width of the silicon oxide film 8 on top of the trench 6 is wider than the trench 6. Therefore, the corners of the trench 6 are protected from exposure by such a lid-like structure. Accordingly, when silicon oxide film 8 on the surface of element region 11 is removed by wet-etching, the development of pockets in silicon oxide film 8 in the corners of trenches 6 is mitigated due to the local progression of the etching of silicon oxide film 8 in the corners of trenches 6 being inhibited.

Nonetheless, the technique mentioned above is problematic since it is difficult to scale-down the size of the element region, which therefore inhibits increased integration of the elements. FIG. 7 shows a cross-section of the trench isolation structure according to formation processes of the above method. As it was mentioned before, since it is necessary to make width 21 of the mask pattern openings larger than width 22 of trenches 6 formed in the silicon substrate 1, width 24 of element region becomes that much (the amount of overlapping) larger than patterning length 23 of the three-layer film 2, 3, and 4. Due to manufacturing limitations of the photolithographic apparatus, the scaling-down of patterning length 23 is restricted; however, width 24 of element region normally becomes larger than these limitations so that downsizing down to the shortest length allowed by the photolithographic apparatus manufacturing limits is impossible. As a result, the scaling-down of the width 24 of the element region is restricted as well as the corresponding increased chip integration.

### SUMMARY OF THE INVENTION

The present invention aims to mitigate the development of pockets in the insulating film in the corners of trenches.

It also aims to provide a formation process for trench isolations wherein the size of the element region is reduced to the lowest possible length allowed by the manufacturing limitations of the photolithographic apparatus.

A method of forming a trench isolation of the present invention includes, forming a mask pattern with a plurality of openings on a semiconductor substrate, forming a plurality of trenches by etching the semiconductor substrate using the mask pattern as a mask, forming a first insulating film in the trenches and the openings, removing the mask pattern; and forming second insulating films on each side wall of the first insulating film.

### BRIEF DESCRIPTION OF DRAWINGS

The above and other objects, features and advantages of the present invention will become more apparent from the following detailed description, when taken in conjunction with the accompanying drawings, wherein:

FIGS. 1A to 1H are cross-sectional diagrams each showing the respective steps of forming trench isolation according to a first embodiment of the present invention;

FIG. 2 is a cross-sectional diagram showing the structure of trench isolation according to the first embodiment of the present invention;

FIGS. 3A to 3I are cross-sectional diagrams each showing the respective steps of forming trench isolation according to a second embodiment of the present invention;

FIGS. 4A to 4H are cross-sectional diagrams each showing the respective steps of forming trench isolation according to a third embodiment of the present invention; and

FIG. 5 is cross-sectional diagram showing the conventional trench isolation.

FIG. 6A to 6H are cross-sectional diagrams each showing the respective steps of forming conventional trench isolation; FIG. 7 is a cross-sectional diagram showing the conventional trench isolation.

### DETAILED DESCRIPTION OF THE PREFERRED EMBODIMENTS

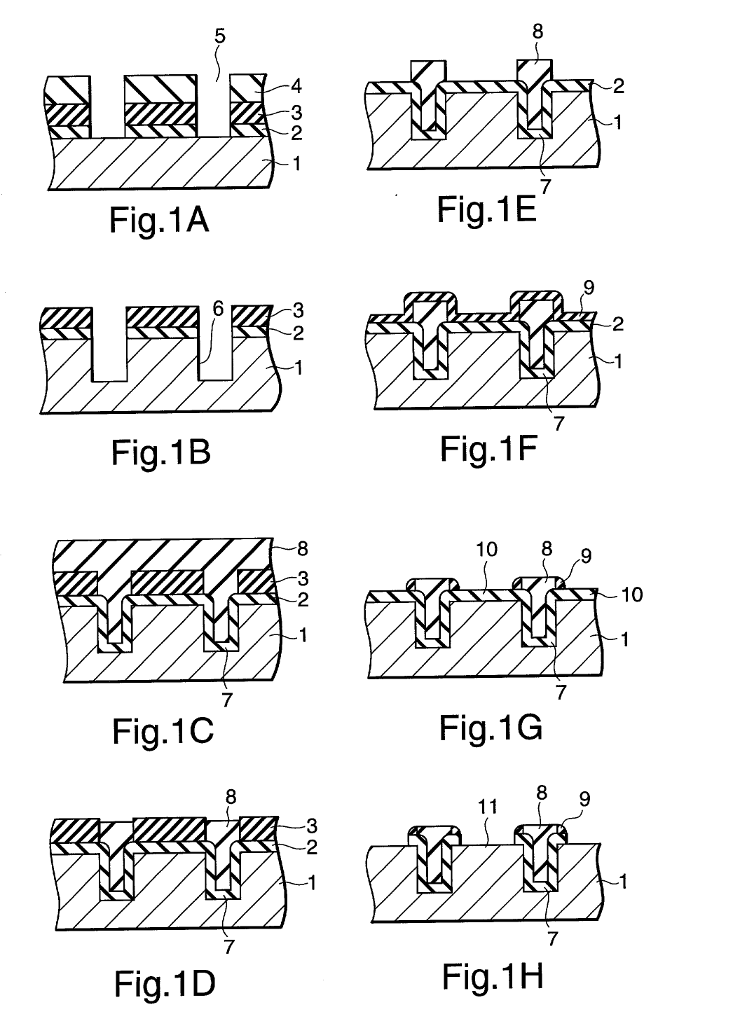

FIGS. 1A to 1H are cross-sectional diagrams each showing the respective steps of forming trench isolation according to a first embodiment of the present invention. As shown in FIG. 1A, the surface of silicon substrate 1 is oxidized so as to form silicon oxide film 2 with a predetermined thickness between, for example, 10 and 30 nm. On this silicon oxide film 2, silicon nitride film 3 is deposited using CVD (chemical vapor deposition) with a predetermined thickness between, for example, 140 and 200 nm. Then another layer of silicon oxide film 4 is deposited on silicon nitride film 3 with a predetermined thickness between, for example, 40 and 300 nm. Next element isolation region patterning is performed using photolithography and the three-layer film 2, 3 and 4 on the element region is etched off using RIE (reactive ion etching) forming openings 5.

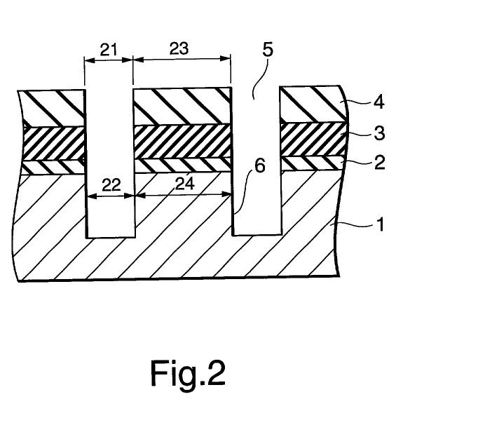

As shown in FIG. 2, the three-layer film 2, 3, and 4 is then used as an etching mask in order to etch silicon substrate 1, for example, down a predetermined depth between 250 and 400 nm, forming trenches 6.

Once this is completed, as shown in FIG. 1B, silicon oxide film 4 is removed and the surface of silicon nitride film 3 is exposed. Next, as shown in FIG. 1C, after the inner walls of trenches 6 have been oxidized and silicon oxide film 7 has been formed with a predetermined thickness between, for example, 20 and 30 nm, a silicon oxide film 8 with a predetermined thickness between, for example, 500 and 600 nm, is deposited using a process such as HDP (high density plasma) or LPCVD (low-pressure CVD), filling in trenches 6 with silicon oxide film 8. At this point, silicon oxide film 8 covers the upper surface of silicon nitride film 3.

Next, as shown in FIG. 1D, the silicon oxide film 8 that had been laid down is etched back using a wet-etching process such as CMP (chemical mechanical polishing) or RIE, exposing the upper surface of silicon nitride film 3.

As shown in FIG. 1E, this silicon nitride film 3 is then removed using wet-etching.

Using LPCVD, another silicon oxide film 9 is formed on top of silicon oxide films 2 and 8 as shown in FIG. 1F with a predetermined thickness between, for example, 20 and 100 nm. Afterwards, as shown in FIG. 1G, silicon oxide films 2 and 9 are etched back until silicon substrate 1 is exposed using full surface RIE, leaving behind a layer of silicon oxide film 9 on the side walls of silicon oxide film 8. The surface of silicon substrate 1 is next oxidized at a predetermined temperature between 850° C. and 1100° C. so as to form silicon oxide film 10 removing the damage on the substrate surface resulting from RIE.

Finally, once ion doping has been performed to facilitate transistor formation, silicon oxide film 10 is removed from element region 11 using wet-etching; thereby completing the formation of isolation trenches on element region 11 shown in FIG. 1H.

According to the present embodiment, by forming silicon oxide film 9 on the side walls of silicon oxide film 8 after silicon nitride film 3 is removed, silicon oxide film 9 acts as a protecting layer for silicon oxide film 8. As a result, the progression of the wet-etching of silicon oxide film 8 in the corners of trenches 6 is blocked; thereby mitigating the development of pockets in silicon oxide film 8 in the corners of trenches 6.

Furthermore, according to the present embodiment and as shown in FIG. 2, width 22 of trenches 6 and width 21 of openings 5 in the etching mask are equal. The patterning length 23 of the three-layer film 2, 3, and 4, and the length 24 of the element region on the silicon substrate 1 also are equal. Therefore it is possible for length 24 of the element region on silicon substrate 1 to be shortened to the shortest length allowed within the manufacturing limits of the photolithographic apparatus.

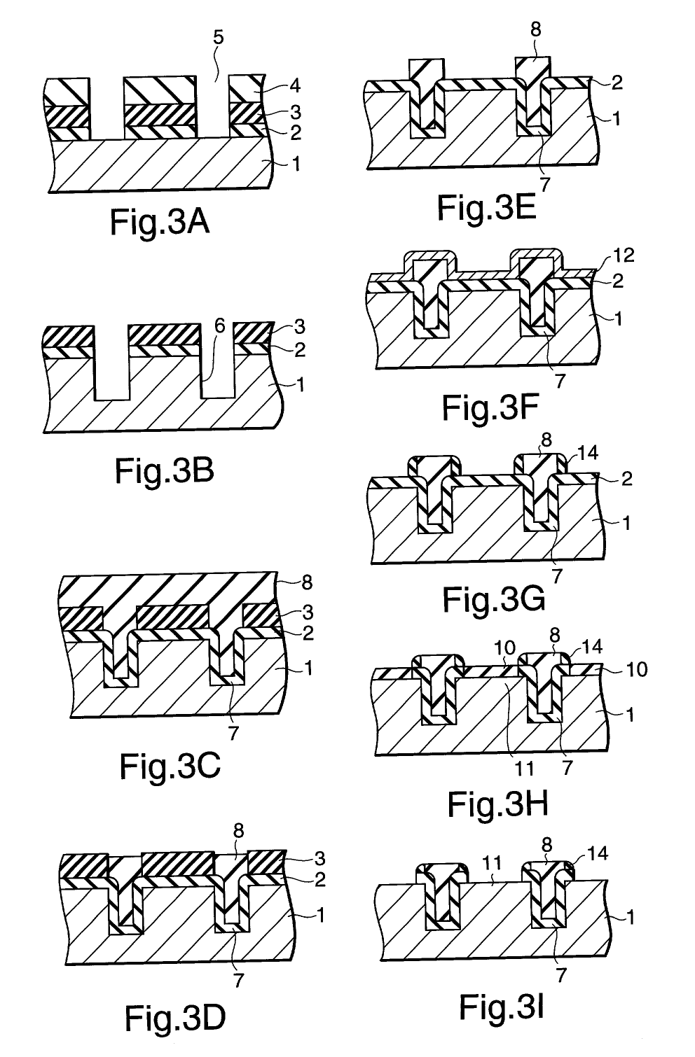

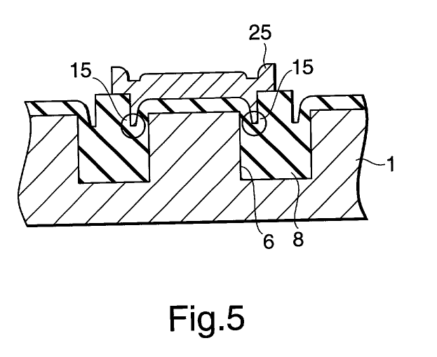

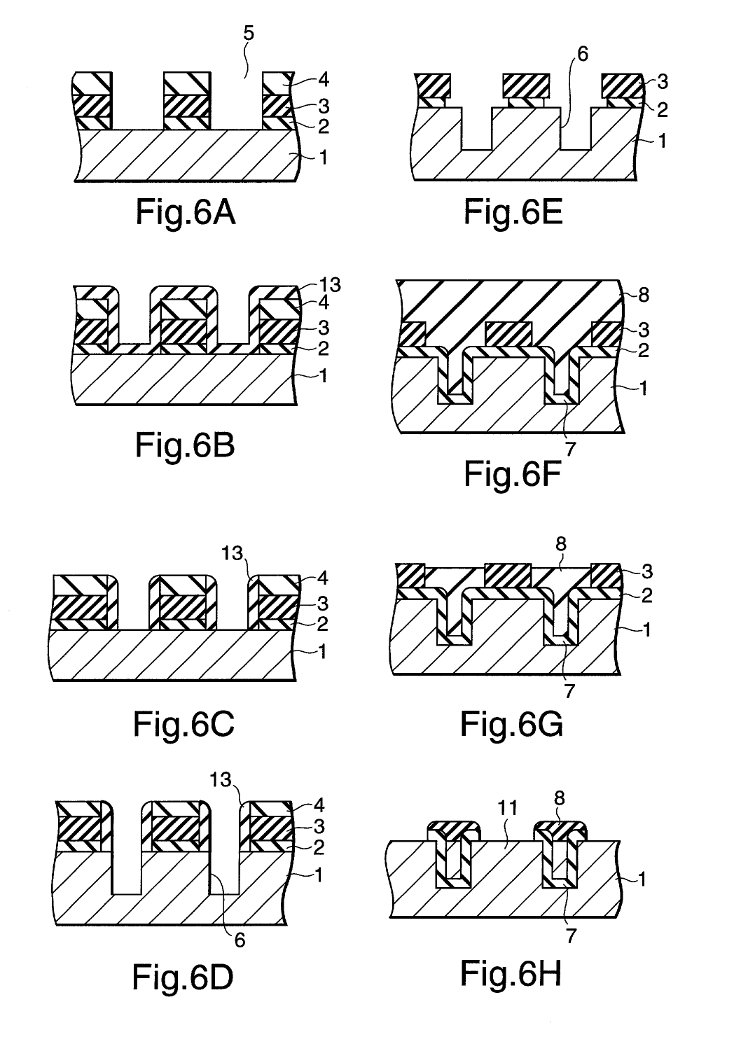

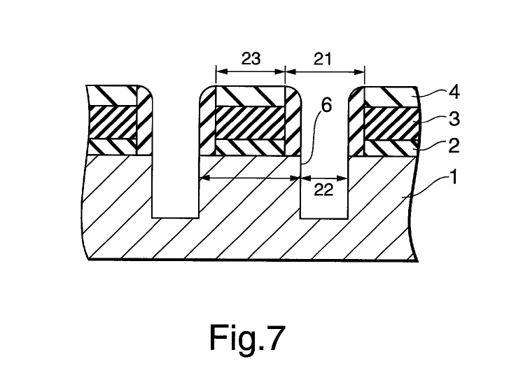

A second embodiment of the present invention will now be described while referencing FIGS. 3a to 3I. The items identical to those in FIGS. 1A to 1H are assigned the same reference numerals in FIGS. 3A to 3I. Moreover, the formation process up until silicon nitride film 3 is removed (shown in FIGS. 3A through 3E) is the same as the formation process according to the first embodiment up until silicon nitride film 3 is removed (shown in FIGS. 1A through 11E).

As shown in FIG. 3A, the surface of silicon substrate 1 is oxidized so as to form silicon oxide film 2 with a predetermined thickness between, for example, 10 and 30 nm. On this silicon oxide film 2, silicon nitride film 3 is deposited using CVD with a predetermined thickness between, for example, 140 and 200 nm. Then another layer of silicon oxide film 4 is deposited on silicon nitride film 3 with a predetermined thickness between, for example, 40 and 300 nm. Next element isolation region patterning is performed using photolithography and the three-layer film 2, 3 and 4 on the element region is etched off using RIE forming openings 5.

As shown in FIG. 2, the three-layer film 2, 3, and 4 is then used as an etching mask in order to etch silicon substrate 1, for example, down a predetermined depth between 250 and 400 nm, forming trenches 6.

Once this is completed, as shown in FIG. 3B, silicon oxide film 4 is removed and the surface of silicon nitride film 3 is exposed. Next, as shown in FIG. 3C, after the inner walls of trenches 6 have been oxidized so as to form silicon oxide film 7 with a thickness of, for example, 20 to 30 nm, a silicon oxide film 8 with a predetermined thickness between, for example, 500 and 600 nm, is deposited using a process such as HDP or LPCVD, filling in trenches 6 with silicon oxide film 8. At this point, silicon oxide film 8 covers the upper surface of silicon nitride film 3.

Next, as shown in FIG. 3D, the silicon oxide film 8 that had been laid down is etched back using a wet-etching process such as CMP or RIE, exposing the upper surface of silicon nitride film 3.

As shown in FIG. 3E, this silicon nitride film 3 is then removed using wet-etching.

A poly-silicon film 12 is next formed on top of silicon oxide films 2 and 8 as shown in FIG. 3F with a predetermined thickness between, for example, 10 and 50 nm. Afterwards, as shown in FIG. 3G, poly-silicon film 12 is etched back to expose silicon oxide films 2 and 8 using full surface RIE, leaving behind a layer of poly-silicon film 12 on the side walls of silicon oxide film 8. Poly-silicon film 12 that has been left behind is then oxidized at a predetermined temperature between 850° C. and 1100° C. transforming poly-silicon film 12 into silicon oxide film 14. Afterwards, as shown in FIG. 3H, silicon oxide film 2 is removed from the surface of element region 11 using wet-etching. The surface of silicon substrate 1 is oxidized at a predetermined temperature between 850° C. and 1100° C. so as to form silicon oxide film 10.

Finally, once ion doping has been performed to facilitate transistor formation, silicon oxide film 10 is removed from element region 11 using wet-etching; thereby completing the formation of isolation trenches on element region 11 shown in FIG. 3I.

In the present embodiment, the same results are obtained as in the first embodiment. In addition, since it is possible to immediately halt etching back poly-silicon film 12 once silicon oxide film 2 has been exposed, damage to the substrate caused by RIE is prevented, which reduces the amount of current needed to turn on the transistors and/or curbs increases in electric current leakage.

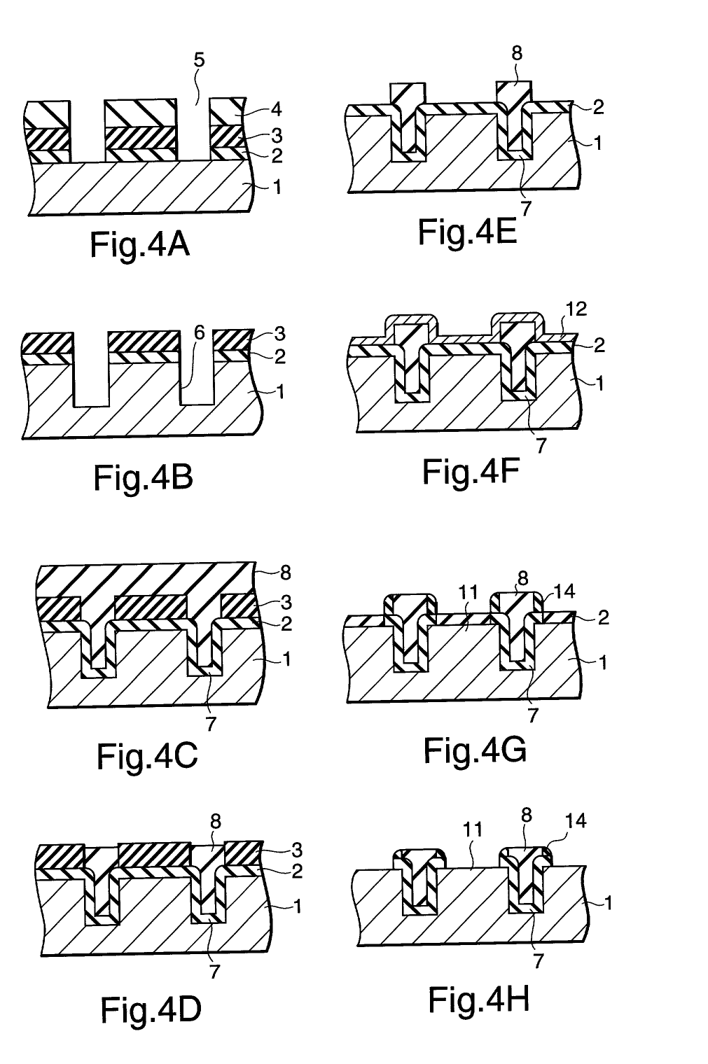

A third embodiment of the present invention will now be described while referencing FIGS. 4A to 4H. The items identical to those in FIGS. 1 and 3 are assigned the same reference numerals in FIG. 4A to 4H. Moreover, the formation process up until poly-silicon film 12 is oxidized forming silicon oxide film 14 (shown in FIGS. 4A through 4G) is the same as the formation process according to the second embodiment up until poly-silicon film 12 is oxidized forming silicon oxide film 14 (shown in FIGS. 3A through 3G).

As shown in FIG. 4A, the surface of silicon substrate 1 is oxidized forming silicon oxide film 2 with a predetermined thickness between, for example, 10 and 30 nm. On this silicon oxide film 2, silicon nitride film 3 is deposited using CVD with a predetermined thickness between, for example, 140 and 200 nm. Then another layer of silicon oxide film 4 is deposited on silicon nitride film 3 with a predetermined thickness between, for example, 40 and 300 nm. Next element isolation region patterning is performed using photolithography and the three-layer film 2, 3 and 4 on the element region is etched off using RIE forming openings 5.

As shown in FIG. 2, the three-layer film 2, 3, and 4 is then used as an etching mask in order to etch silicon substrate 1, for example, down a predetermined depth between 250 and 400 nm, forming trenches 6.

Once this is completed, as shown in FIG. 4B, silicon oxide film 4 is removed and the surface of silicon nitride film 3 is exposed. Next, as shown in FIG. 4C, after the inner walls of trenches 6 have been oxidized and silicon oxide film 7 has been formed with a predetermined thickness between, for example, 20 and 30 nm, a silicon oxide film 8 with a thickness between, for example, 500 and 600 nm, is deposited using a process such as HDP or LPCVD, filling in trenches 6 with silicon oxide film 8. At this point, silicon oxide film 8 covers the upper surface of silicon nitride film 3.

Next, as shown in FIG. 4D, the silicon oxide film 8 that had been laid down is etched back using a wet-etching process such as CMP or RIE, exposing the upper surface of silicon nitride film 3.

As shown in FIG. 4E, this silicon nitride film 3 is then removed using wet-etching.

Poly-silicon film 12 is next formed on top of silicon oxide films 2 and 8 as shown in FIG. 4F with a predetermined thickness between, for example, 10 and 50 nm. Afterwards, as shown in FIG. 4G, poly-silicon film 12 is etched back to expose silicon oxide films 2 and 8 using full surface RIE, leaving behind a layer of poly-silicon film 12 on the side walls of silicon oxide film 8. Poly-silicon film 12 that has been left behind is then oxidized at predetermined temperature between 850° C. and 1100° C. transforming poly-silicon film 12 into silicon oxide film 14.

Finally, without removing silicon oxide film 2 using wet-etching, ion doping is performed to facilitate transistor formation. Afterwards, as shown in FIG. 4H, silicon oxide film 2 is removed from element region 11 using wet-etching, completing the formation of isolation trenches.

In the present embodiment, the same results are obtained as in the second embodiment. In addition, it is possible to simplify the process by not having to remove silicon oxide film 2 before performing ion doping. Moreover, by omitting the process step of removing silicon oxide film 2 by wet-etching, since the etching progression on the oxidized film in trench corners is kept in check, it is possible to mitigate the development of pockets in the oxidized film in the corners of trenches.

In the present invention, after trenches 6 are formed using RIE, it is possible to perform wet-etching and/or heat-treatments in order to restore to normal the damage caused by RIE. Once silicon oxide film 7 is formed on the inner walls of trenches 6, it is also possible to form, for example, silicon nitride film, silicon oxide film, or their respective insulating films using CVD, and then filling in openings 5 or trenches 6 with silicon oxide film 8. Moreover, heat treatments and oxidization treatments have been included in the present invention in order to increase the wet-etching tolerance of silicon oxide film 8, after silicon oxide film 8 has been used to fill up openings 5 or trenches 6, and likewise, after silicon oxide film 8 has been etched back exposing silicon nitride film 3. Furthermore, the present invention also allows for silicon oxide films 9 and 14, which are formed on the side walls of silicon oxide film 8, to be removed during the final wet-etching process.

As mentioned earlier, according to the present invention, by setting up a side wall from a secondary insulating layer, on the side wall of the primary insulating layer that fills in the trenches, the corners (which are normally the areas most sensitive to etching) are protected during the wet-etching process that removes the silicon oxide film from the surface of the element region. Etching progression along the insulating film in these areas is inhibited, making it possible to reduce the development of pockets in the insulating film. Furthermore, by making the length of mask pattern openings 5 throughout the semiconductor substrate equal to the width of trenches 6, the length of the element region can be shortened to the lowest possible length allowed within manufacturing limitations of the photolithographic apparatus. As a result, drops in the transistor threshold voltage and current leakage, which help cause pockets to form in the insulating film in the corners of the trenches, are reduced, and production of smaller semiconductor integrated circuits with higher integration is made possible.

Methods of forming shallow trench isolations, according to the present invention, have been described in connection with several preferred embodiments. It is to be understood that the subject matter encompassed by the present invention is not limited to that specified embodiment. On the contrary, it is intended to include as many alternatives, modifications, and equivalents as can be included within the spirit and scope of the following claims.

What is claimed is:

1. A method of forming a trench isolation comprising: forming a mask pattern with a plurality of openings on a semiconductor substrate;
forming a plurality of trenches by etching said semiconductor substrate using said mask pattern as a mask;
forming a first insulating film in said trenches and said openings;
removing said mask pattern; and
forming second insulating films on each side wall of said first insulating film.

2. The method according to claim 1, said method further comprising after forming said second insulating films:
oxidizing an surface of said semiconductor substrate to form a silicon oxide film;
introducing a plurality of element regions on said semiconductor substrate with ions; and
removing said silicon oxide film from said element region.

3. The method according to claim 2, wherein said second insulating films are formed by
depositing an insulation layer on whole surface of said semiconductor substrate; and
etching back said insulation layer.

4. The method according to claim 1, wherein said second insulating films is made of a silicon oxide film.

5. The method according to claim 1, wherein said second insulating films are formed using an LPCVD process.

6. The method according to claim 4, wherein said second insulating film is formed by
forming a silicon film on whole surface of said semiconductor substrate;
etching back to expose said first insulating film to form pieces of silicon layers on each side wall of said first insulating film; and
converting said pieces of silicon layers into said second insulating films.

7. A method of forming a trench isolation, comprising:
forming a first insulating film on a semiconductor substrate;
forming a second insulating film on said first insulating film;
patterning said first and second insulating films to form an opening therethrough;
forming a trench on said semiconductor substrate by using the pattern first and second insulating films as a mask;
forming a third insulating film on surfaces of said semiconductor substrate exposed by said trench;
forming a fourth insulating film in said trench and said opening;
removing the patterned first and second insulating films so that said fourth insulating film has a projecting portion from surfaces of said semiconductor substrate;
forming side walls of said projecting portion of said fourth insulating film;
then conducting wet-etching.

8. The method as claimed in claim 7, said method further comprising:
after removing the patterned first and second insulating films, forming a fifth insulating film over whole surface of said semiconductor substrate;
etching back said fifth and first insulating films to expose surface of said semiconductor substrate thereby forming said side walls;
forming a sixth insulating film on the exposed surface of said semiconductor substrate; and
removing said sixth insulating film with said wet-etching.

9. The method as claimed in claim 7, said method further comprising:
after removing the patterned first and second insulating films,
depositing a silicon film over whole surface of said semiconductor substrate;
etching back said silicon film to expose surface of said first insulating film thereby forming pieces of silicon layers on side surfaces of projecting portion;
converting said pieces of silicon layers into said side walls by oxidation; and
removing said first insulating film to expose surface of said semiconductor substrate;
forming a thermal oxide film on the exposed surface of said semiconductor substrate; and
removing said thermal oxide film by wet etching.

10. The method as claimed in claim 7, said method further comprising:
after removing the patterned first and second insulating films,
depositing a silicon film over whole surface of said semiconductor substrate;
etching back said silicon film to expose surface of said first insulating film thereby forming pieces of silicon layers on side surfaces of projecting portion;
converting said pieces of silicon layers into said side walls by oxidation; and
removing said first insulating film to expose surface of said semiconductor substrate by wet etching.

11. A method of forming a trench isolation comprising:
forming an oxide film on a semiconductor substrate;
forming a nitride film on a semiconductor substrate;
patterning said oxide and said nitride films to form a patterned layer; and
then etching said semiconductor substrate by using said patterned layer as a mask to form a trench on said semiconductor substrate.

12. The method as claimed in claim 11, said method further comprising:
after forming said trench forming a thermal oxide film on surfaces of said semiconductor substrate exposed by said trench.

13. The method as claimed in claim 12, said method further comprising:
after forming a thermal oxide film depositing an oxide film on said thermal oxide film.
